(19) United States
(12) Patent Application Publication
(10) Pub. No.: US 2013/0066580 A1
(43) Pub. Date: Mar. 14, 2013

(54) AUTOMATIC MEASURING METHOD AND APPARATUS FOR MEASURING CONNECTING LINES

(71) Applicants: CHANG-YI CHEN, Taipei (TW); Shih-Tung Lin, Taipei (TW); Chen-Yung Lin, Taipei (TW)

(72) Inventors: CHANG-YI CHEN, Taipei (TW); Shih-Tung Lin, Taipei (TW); Chen-Yung Lin, Taipei (TW)

(73) Assignee: Luxshare-ICT Co., LTD., Taipei City (TW)

(21) Appl. No.: 13/301,770

(22) Filed: Nov. 21, 2011

(30) Foreign Application Priority Data
Sep. 8, 2011 (CN) 201110265360.0

(51) Int. Cl. G01R 31/28

(52) U.S. Cl. 702/119

(57) ABSTRACT

An automatic measuring method for measuring connecting lines includes the steps of: S1, loading setting parameters and measuring regulations corresponding to the connecting lines into an automatic measuring apparatus; S2, receiving triggering signals to start measuring; and S3, automatically controlling measuring signals according to the setting parameters to measure multiple pairs of leads of the connecting lines one by one, and then determining whether the quality of the connecting lines is in compliance with standard regulations or not. Besides, an automatic measuring apparatus corresponding to the method is provided as well. The automatic measuring method and the apparatus are suitable for meeting the requirements of product measuring in mass production due to short time and high efficiency.

### BACKGROUND OF THE INVENTION

1. Field of the Invention

The present invention relates to a measuring method and an apparatus for measuring connecting lines, and more particularly to a measuring method and a corresponding apparatus for measuring connecting lines, automatically.

2. Description of Related Art

Generally, multiple parameters of each pair of leads of the connecting lines must be checked in order to determine whether the quality of the connecting lines is in compliance with the standard regulations or not, according to ultimate measuring result data.

The conventional method for measuring connecting lines is manually operating a measuring apparatus so as to measure multiple pairs of leads of the connecting lines. However, such measuring method needs long time and lacks of efficiency, so that it is not suitable for measuring products in mass production. For example, if a connecting line has 5 pairs of connecting leads and each pair of connecting leads require 7 parameters to be measured, at least one hour must be spent under the conventional method to accomplish measuring such connecting line. If a product line manufactures 4000 connecting lines per day, at least 208 days are needed to measure out all the connecting lines.

Hence, an improved measuring method and a corresponding apparatus for measuring connecting lines with high efficiency are desired.

### BRIEF SUMMARY OF THE INVENTION

The present invention provides an automatic measuring method for measuring connecting lines. The method includes the steps of: S1, loading setting parameters and measuring regulations corresponding to the connecting lines into an automatic measuring apparatus; S2, receiving triggering signals to start measuring; and S3, automatically controlling measuring signals according to the setting parameters to measure multiple pairs of leads of the connecting lines one by one, and then determining whether the quality of the connecting lines is in compliance with standard regulations or not.

The present invention also provides an automatic measuring apparatus for measuring connecting lines. The apparatus includes a loading unit, a triggering unit and a measuring unit. The loading unit is adapted for loading setting parameters and measuring regulations corresponding to the connecting lines into an automatic measuring apparatus. The triggering unit is adapted for receiving triggering signals to start measuring. The measuring unit is adapted for automatically controlling measuring signals according to the setting parameters so as to measure multiple pairs of leads of the connecting lines one by one, and then determining whether the quality of the connecting lines is in compliance with standard regulations or not. The automatic measuring method and the automatic measuring apparatus are suitable for meeting the requirements of product measuring in mass production because of short time and high efficiency.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a flow diagram showing an automatic measuring method for measuring connecting lines in accordance with an illustrated embodiment of the present disclosure;

FIG. 2 is a detailed flow diagram of step S2 as shown in FIG. 1;

FIG. 3 is a detailed flow diagram of step S3 as shown in FIG. 1;

FIG. 4 is a flow diagram before step S1 of FIG. 1; and

FIG. 5 is a schematic view showing each unit of an automatic measuring apparatus for measuring connecting lines in accordance with an illustrated embodiment of the present disclosure.

### DETAILED DESCRIPTION OF THE ILLUSTRATED EMBODIMENTS

Reference will be made to the drawing figures to describe the present invention in detail. However, illustrated embodiments should not be used to restrict the present invention. Changes, such as in matters of structure, method or function, may be made to those of ordinary skill in the art according to the principles of the invention, and such changes should also be within the protection scope of the present invention.

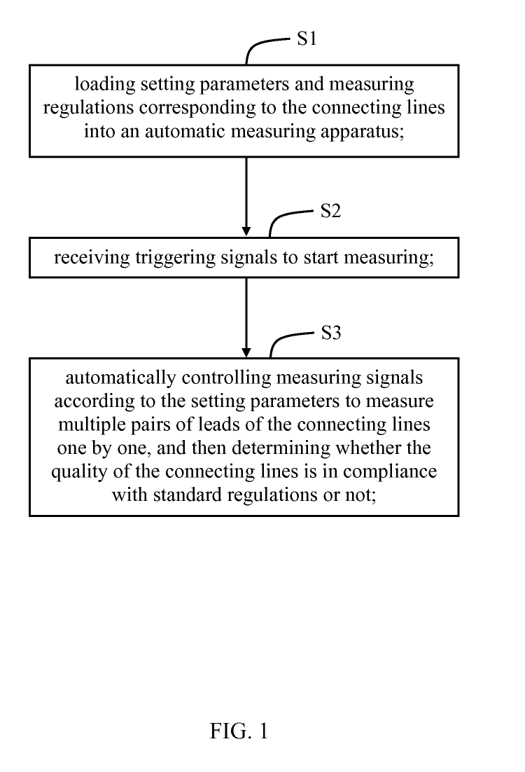

Referring to FIG. 1, an automatic measuring method for measuring connecting lines is disclosed according to an illustrated embodiment of the present disclosure. The method includes the following steps S1, S2, S3 each of which will be described in detail hereinafter.

In step S1, setting parameters and relative measuring regulations corresponding to the connecting lines are loaded into an automatic measuring apparatus. Preferably, the setting parameters, such as Impedance, Intra-Pair Skew, Insertion Loss, Return Loss and Near-End Crosstalk etc., are capable of guiding the automatic measuring apparatus measuring the connecting lines under predetermined procedures. The measuring regulations can be standard coefficients, such as threshold or interval etc., used for being compared with measuring result data so as to ultimately determine whether the quality of the connecting lines is in compliance with the standard regulations or not. Certainly, according to different types of the connecting lines to be measured, corresponding standard coefficients of the measuring regulations are different.

According to the preferred embodiment of the present disclosure, the process of loading the setting parameters into the measuring apparatus is achieved via running the measuring procedures of the measuring apparatus. In such process, basic measuring procedures are preset in the measuring apparatus and can automatically load the setting parameters into the measuring apparatus. Preferably, the measuring procedures and the setting parameters are stored independently in the same or different storage devices, such as data centers or compact disks. Under this setting, the measuring procedures can not be influenced even if the setting parameters needed to be amended or adjusted, as a result that the convenience of the measuring apparatus can be greatly enhanced.

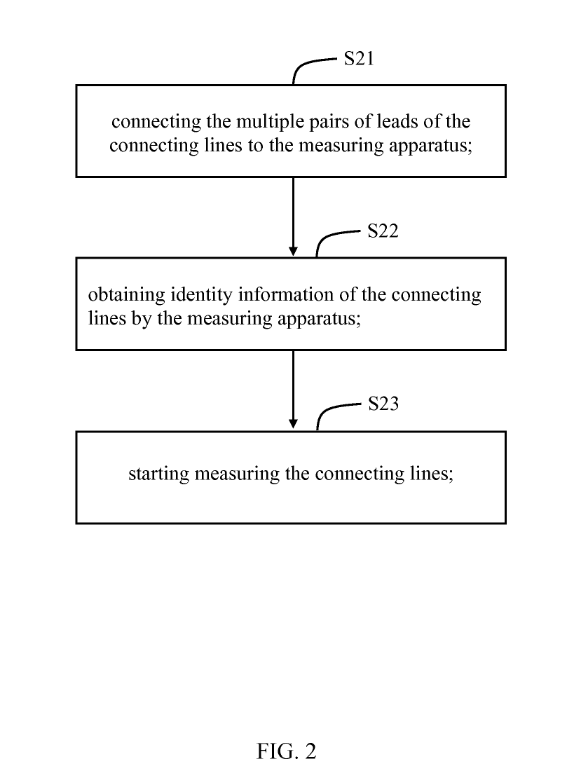

In step S2, triggering signals are received so as to start measuring. Referring to FIG. 2 of the illustrated embodiment of the present disclosure, the step S2 includes the following detailed sub-steps S21, S22, and S23.

In sub-step S21, multiple pairs of leads of the connecting lines are connected to the measuring apparatus. Preferably, the multiple pairs of leads of the connecting lines to be measured can be electrically connected to the measuring apparatus, automatically. One thing deserves to be mentioned is that once automatically measuring some connecting lines gets finished, the system will automatically disconnect such connecting lines from the measuring apparatus to make sure that the subsequent remain connecting lines can be automatically measured. In a word, measuring the connecting lines can be achieved automatically in such sub-step.

In sub-step S22, identity information of the connecting lines is obtained by the measuring apparatus. Preferably, the connecting lines each have a unique mark for representing their corresponding identity. In such sub-step, the measuring apparatus is capable of automatically scanning the marks of the connecting lines to automatically collect the identity information of the connecting lines. In detail, according to the preferred embodiment of the present disclosure, the marks can be barcode or RFID (Radio Frequency Identification), and the identity information is the ID information of the connecting lines.

In sub-step S23, the connecting lines begin to be measured. The above identity information is identified via triggering signals which are received by the measuring apparatus, and then, the connecting lines begin to be measured.

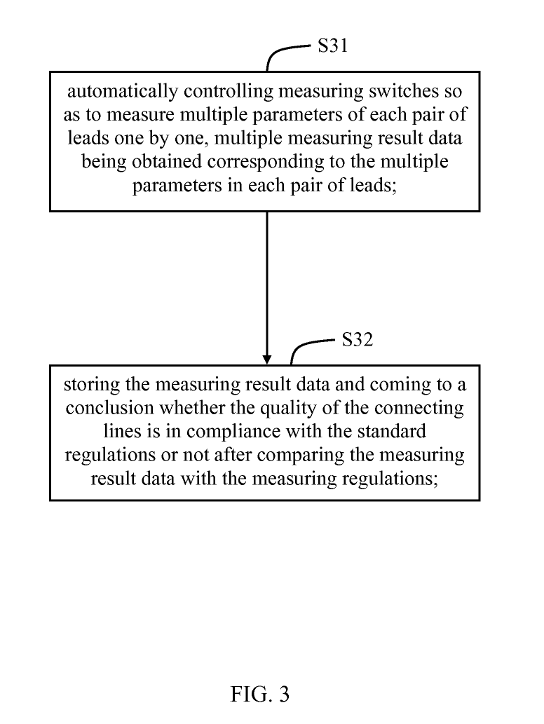

In step S3, the multiple pairs of leads of the connecting lines are measured one by one according to the measuring signals automatically controlled by the setting parameters, and then whether the quality of the connecting lines in compliance with the standard regulations or not is determined. Referring to FIG. 3 of the illustrated embodiment of the present disclosure, the step S3 includes the following detailed sub-steps S31 and S32.

In sub-step S31, measuring switches are automatically controlled so as to measure multiple parameters, such as Impedance, Intra-Pair Skew, Insertion Loss, Return Loss and Near-End Crosstalk etc., of each pair of leads one by one. Regarding each pair of leads, multiple measuring result data is obtained corresponding to the multiple parameters. During such sub-step, the measuring apparatus automatically controls the required measuring switches, such as high frequency switches, according to the setting parameters. Then, the measuring apparatus will measure each and every parameter of the pair of leads after inputting measuring signals into such pair of leads. When measuring the parameters of the pair of leads gets finished, the measuring switches are shifted to another pair of leads. Similarly, the measuring apparatus will measure each and every parameter of the another pair of leads after inputting measuring signals into such pair of leads. The above processes are circulated till the parameters of the ultimate pair of leads are measured out. In a word, the measuring time is greatly decreased because the heavy load of manual switching is avoided.

In sub-step S32, the measuring result data is stored and the final conclusion comes into being after comparing the result data with the measuring regulations. After one of the connecting lines is measured out, the measuring result data is automatically stored in the storage device and the measuring result data is compared with the standard regulations to determine whether the quality of the connecting line is in compliance with the standard regulations or not. For example, the judging standard of the measuring regulations corresponding to some parameters can be set in an interval. If the measuring result data is within the interval, the parameter can be regarded in compliance with the standard regulation. Contrarily, if the measuring result data goes beyond the interval, the parameter can be regarded not in compliance with the standard regulation. When all the parameters are measured and compared to be located within corresponding intervals, the connecting lines can be regarded in compliance with the standard regulations. Preferably, after judging whether the connecting lines are in compliance with the standard regulations or not, measurement reports and/or statistical materials can be automatically created, and such measurement reports and/or statistical materials can be stored and/or sent to managers or technical staffs for them to control in real time the product percent of pass and reasons for disqualification.

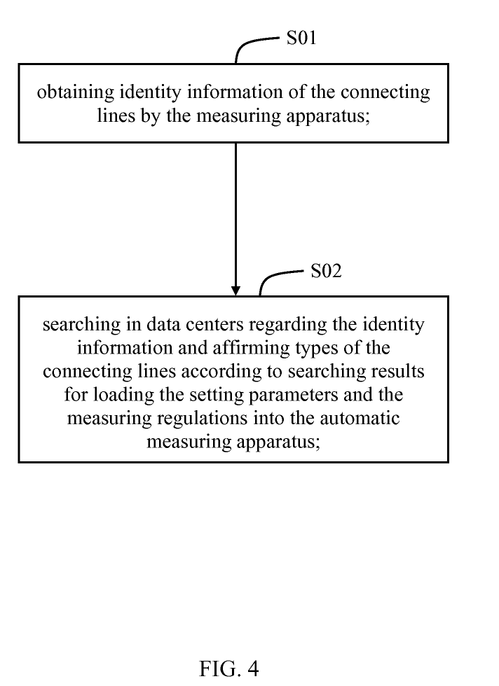

Referring to FIG. 4, before the step S1, steps S01 and S02 are included.

In step S01, identity information of the connecting lines is obtained by the measuring apparatus. Preferably, the connecting lines each have a unique mark for representing their corresponding identity. In such sub-step, the measuring apparatus is capable of automatically scanning the marks of the connecting lines to automatically collect the identity information of the connecting lines. In detail, according to the preferred embodiment of the present disclosure, the marks can be barcode or RFID (Radio Frequency Identification), and the identity information is the ID information of the connecting lines.

In step S02, a work searching in the data centers regarding the identity information is done and the types of the connecting lines according to the searching results are affirmed. Then, the setting parameters and relative measuring regulations corresponding to the connecting lines are loaded into the automatic measuring apparatus. Preferably, indexes adapted for searching the types of the connecting lines through identity information are stored in the data centers. Through searching such indexes, the types of the connecting lines can be matched or obtained corresponding to the identity information. For example, if the identity information of the connecting lines is “01”, through searching the indexes of “01”, the type of connecting lines, such as USB, corresponding to “01” can be matched.

The types of the connecting lines to be measured can be automatically affirmed in such steps before the step Si so that the measuring regulations corresponding to the connecting lines can be correctly loaded in the step S1.

It is noticed that all the above steps can be finished under automatically controlling by the system, and have no need of manual operations.

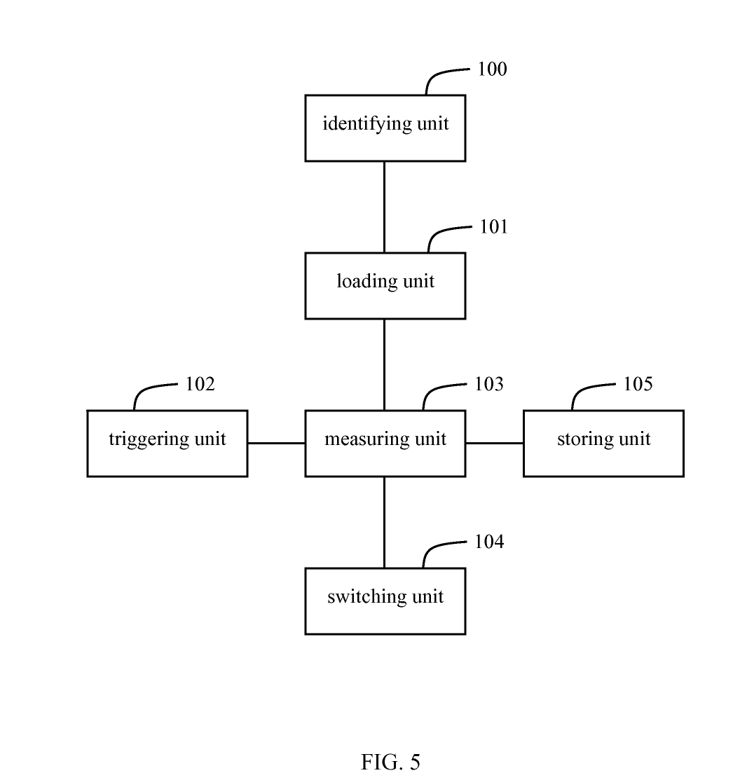

Referring to FIG. 5, an automatic measuring apparatus for measuring connecting lines is disclosed according to an illustrated embodiment of the present disclosure. The apparatus includes a loading unit 101, a triggering unit 102, a measuring unit 103, a switching unit 104 and a storing unit 105. The description of each unit will be detailed hereinafter.

The loading unit 101 is adapted for loading setting parameters and relative measuring regulations corresponding to the connecting lines into the automatic measuring apparatus. Preferably, the setting parameters, such as Impedance, Intra-Pair Skew, Insertion Loss, Return Loss and Near-End Crosstalk etc., are capable of guiding the automatic measuring apparatus measuring the connecting lines under predetermined procedures. The measuring regulations can be standard coefficients, such as threshold or interval etc., used for being compared with measuring result data so as to ultimately determine whether the quality of the connecting lines is in compliance with the standard regulations or not. Certainly, according to different types of the connecting lines to be measured, corresponding standard coefficients of the measuring regulations are different.

According to the preferred embodiment of the present disclosure, the process of loading the setting parameters into the measuring apparatus is achieved via running the measuring procedures of the measuring apparatus. In such process, basic measuring procedures are preset in the measuring apparatus and can automatically load the setting parameters into the measuring apparatus. Preferably, the measuring procedures and the setting parameters are stored independently in the same or different storage devices, such as data centers or compact disks. Under this setting, the measuring procedures can not be influenced even if the setting parameters needed to be amended or adjusted, as a result that the convenience of the measuring apparatus can be greatly enhanced.

The triggering unit 102 is adapted for receiving triggering signals so as to start measuring. In detail, the triggering unit 102 is applied to connect multiple pairs of leads of the connecting lines to the measuring apparatus, obtain identity information of the connecting lines by the measuring apparatus, and start measuring the connecting lines.

Preferably, the multiple pairs of leads of the connecting lines to be measured can be electrically connected to the measuring apparatus, automatically. One thing deserves to be mentioned is that once automatically measuring some connecting lines gets finished, the system will automatically disconnect such connecting lines from the measuring apparatus to make sure that the subsequent remain connecting lines can be automatically measured. In a word, measuring the connecting lines can be achieved automatically.

The connecting lines each have a unique mark for representing their corresponding identity. The measuring apparatus is capable of automatically scanning the marks of the connecting lines to automatically collect the identity information of the connecting lines. In detail, according to the preferred embodiment of the present disclosure, the marks can be barcode or RFID (Radio Frequency Identification), and the identity information is the ID information of the connecting lines.

The above identity information is identified via triggering signals which are received by the measuring apparatus. Then, the connecting lines begin to be measured.

The measuring unit 103 is adapted for measuring the multiple pairs of leads of the connecting lines one by one according to the measuring signals automatically controlled by the setting parameters, and then determining whether the quality of the connecting lines is in compliance with the standard regulations or not.

The measuring unit 103 is capable of automatically controlling the measuring switches via the switching unit 104 so as to measure multiple parameters, such as Impedance, Intra-Pair Skew, Insertion Loss, Return Loss and Near-End Crosstalk etc., of each pair of leads one by one. Regarding each pair of leads, multiple measuring result data is obtained corresponding to the multiple parameters. The measuring apparatus automatically controls the required measuring switches, such as high frequency switches, according to the setting parameters. Then, the measuring apparatus will measure each and every parameter of the pair of leads after inputting measuring signals into such pair of leads. When measuring the parameters of the pair of leads gets finished, the measuring switches are shifted to another pair of leads. Similarly, the measuring apparatus will measure each and every parameter of the another pair of leads after inputting measuring signals into such pair of leads. The above processes are circulated till the parameters of the ultimate pair of leads are measured out. In a word, the measuring time is greatly decreased because the heavy load of manual switching is avoided.

The measuring result data measured out by the measuring unit 103 can be stored in the storing unit 105, and the final conclusion comes into being after comparing the result data with the measuring regulations. After one of the connecting lines is measured out, the measuring result data is automatically stored in the storage device and the measuring result data is compared with the standard regulations to determine whether the quality of the connecting line is in compliance with the standard regulations or not. For example, the judging standard of the measuring regulations corresponding to some parameters can be set in an interval. If the measuring result data is within the interval, the parameter can be regarded in compliance with the standard regulation. Contrarily, if the measuring result data goes beyond the interval, the parameter can be regarded not in compliance with the standard regulation. When all the parameters are measured and compared to be located within corresponding intervals, the connecting lines can be regarded in compliance with the standard regulations. Preferably, after judging whether the connecting lines are in compliance with the standard regulations or not, measurement reports and/or statistical materials can be automatically created, and such measurement reports and/or statistical materials can be stored and/or sent to managers or technical staffs for them to control in real time the product percent of pass and reasons for disqualification.

Referring to FIG. 5, the measuring apparatus further includes an identifying unit 100 adapted for obtaining identity information of the connecting lines. Preferably, the connecting lines each have a unique mark for representing their corresponding identity. In such step, the measuring apparatus is capable of automatically scanning the marks of the connecting lines to automatically collect the identity information of the connecting lines. In detail, according to the preferred embodiment of the present disclosure, the marks can be barcode or RFID (Radio Frequency Identification), and the identity information is the ID information of the connecting lines.

The identifying unit 100 is also adapted for searching in the data centers regarding the identity information and affirming the types of the connecting lines according to the searching results. Then, the setting parameters and relative measuring regulations corresponding to the connecting lines are loaded into the automatic measuring apparatus. Preferably, indexes adapted for searching the types of the connecting lines through identity information are stored in the data centers. Through searching such indexes, the types of the connecting lines can be matched or obtained corresponding to the identity information. For example, if the identity information of the connecting lines is “01”, through searching the indexes of “01”, the type of connecting lines, such as USB, corresponding to “01” can be matched.

The types of the connecting lines to be measured can be automatically affirmed by the identifying unit 100 so that the measuring regulations corresponding to the connecting lines can be correctly loaded in the loading unit 101.

It is noticed that all the steps executed by the corresponding units are automatically controlled by the system, and have no need of manual operations.

In a word, the automatic measuring method and the automatic measuring apparatus according to the present invention are capable of measuring the connecting lines automatically, as a result that the automatic measuring method and the automatic measuring apparatus are suitable for meeting the requirements of product measuring in mass production because of short time and high efficiency.

The illustrated embodiment of the automatic measuring apparatus shown in FIG. 5 and described above is schematic. It is understood that the units 100-105 separately described above can be separated or connected in physics. Display components of a display unit can be or cannot be physics units, and the display components can be located in a same position or dispersed in different web units. It is easy for those of ordinary skill in the art, without any creative work, to understand that part of or all of the units 100-105 can be selected according to actual requirements to realize the purpose of the present invention.

In the above description of the automatic measuring apparatus, for convenient description, the units 100-105 with different functions are separately described. However, it is understood that even if the units 100-105 have different functions, they can be integrated in one or more software and/or hardware to realize the purpose of the present invention as well.

According to the above description, it is understood to those skilled in the art that the present invention can also be realized by software together with needed universal hardware platforms. Based on such conception, technical solutions, also known as the parts that define a contribution making over the prior arts, of the present invention can be essentially represented by software products. Such software products can be stored in storage mediums such as ROM/RAM, magnetic-discs, compact disks etc. The software products include multiple instructions for a computer device, such as a personal computer, a server, or a network equipment, running to execute the steps of each embodiment or part of the embodiments of the present invention.

The present invention can be applied into multiple universal or special computer system environments or accessories, such as personal computers, servers, handheld devices or portable devices, tablet devices, multiprocessor systems, microprocessor systems, set-top boxes, programming consumer electronic devices, network PCs, small scale computers, large scale computers, or distributed computer environments of any above systems or devices etc.

The present invention can be applied in the contexts, such as program units, which are carried out by computer execute instructions of computers. Generally, the program units include routines, programs, objects, components and data structures etc. which are used for executing special designated tasks or realizing special designated abstract data types. The present invention can also be applied in the distributed computer environments via remote processing equipments which are connected by communication networks to execute tasks. In such distributed computer environments, the program units can lie in the storage mediums of local or remote computers, including storage devices.

It is to be understood, however, that even though numerous, characteristics and advantages of the present invention have been set forth in the foregoing description, together with details of the structure and function of the invention, the disclosed is illustrative only, and changes may be made in detail, especially in matters of number, shape, size, and arrangement of parts within the principles of the invention to the full extent indicated by the broadest general meaning of the terms in which the appended claims are expressed.

What is claimed is:

1. An automatic measuring method for measuring connecting lines, comprising steps of:
S1, loading setting parameters and measuring regulations corresponding to the connecting lines into an automatic measuring apparatus;
S2, receiving triggering signals to start measuring; and
S3, automatically controlling measuring signals according to the setting parameters to measure multiple pairs of leads of the connecting lines one by one, and then determining whether the quality of the connecting lines is in compliance with standard regulations or not.

2. The automatic measuring method as claimed in claim 1, wherein, in the step S1, the setting parameters are loaded into the measuring apparatus via running measuring procedures of the measuring apparatus.

3. The automatic measuring method as claimed in claim 2, wherein the measuring procedures and the setting parameters are stored independently.

4. The automatic measuring method as claimed in claim 1, wherein the step S2 comprises following sub-steps:
S21, connecting the multiple pairs of leads of the connecting lines to the measuring apparatus;
S22, obtaining identity information of the connecting lines by the measuring apparatus; and
S23, starting measuring the connecting lines.

5. The automatic measuring method as claimed in claim 4, wherein, in the step S21, the multiple pairs of leads of the connecting lines are connected to the measuring apparatus, automatically.

6. The automatic measuring method as claimed in claim 1, wherein the step S3 comprises a following sub-step:
S31, automatically controlling measuring switches so as to measure multiple parameters of each pair of leads one by one, multiple measuring result data being obtained corresponding to the multiple parameters in each pair of leads.

7. The automatic measuring method as claimed in claim 6, wherein the step S3 comprises another following sub-step after the sub-step S31:
S32, storing the measuring result data and coming to a conclusion whether the quality of the connecting lines is in compliance with the standard regulations or not after comparing the measuring result data with the measuring regulations.

8. The automatic measuring method as claimed in claim 1, further comprising the following steps before the step S1:
S01, obtaining identity information of the connecting lines by the measuring apparatus; and
S02, searching in data centers regarding the identity information and affirming types of the connecting lines according to searching results for loading the setting parameters and the measuring regulations into the automatic measuring apparatus.

9. The automatic measuring method as claimed in claim 8, wherein, in the step S02, indexes adapted for searching the types of the connecting lines through the identity information are stored in the data centers.

10. An automatic measuring apparatus for measuring connecting lines, comprising:
a loading unit to load setting parameters and measuring regulations corresponding to the connecting lines into an automatic measuring apparatus;
a triggering unit to receive triggering signals to start measuring; and
a measuring unit to automatically control measuring signals according to the setting parameters so as to measure multiple pairs of leads of the connecting lines one by one, and then to determine whether the quality of the connecting lines is in compliance with standard regulations or not.

11. The automatic measuring apparatus as claimed in claim 10, wherein the setting parameters are loaded into the measuring apparatus by the loading unit via running measuring procedures of the measuring apparatus.

12. The automatic measuring apparatus as claimed in claim 11, wherein the measuring procedures and the setting parameters are stored independently.

13. The automatic measuring apparatus as claimed in claim 10, wherein the triggering unit is adapted for connecting the multiple pairs of leads of the connecting lines to the measuring apparatus, obtaining identity information of the connecting lines by the measuring apparatus, and starting measuring the connecting lines.

14. The automatic measuring apparatus as claimed in claim 10, wherein the automatic measuring apparatus comprises a switching unit through which the measuring unit is capable of automatically controlling measuring switches so as to measure multiple parameters of each pair of leads one by one, multiple measuring result data being obtained corresponding to the multiple parameters in each pair of leads.

15. The automatic measuring apparatus as claimed in claim 14, wherein the automatic measuring apparatus comprises a storing unit in which the measuring result data is stored, a conclusion whether the quality of the connecting lines is in compliance with the standard regulations or not comes into being after comparing the measuring result data with the measuring regulations.

16. The automatic measuring apparatus as claimed in claim 10, wherein the automatic measuring apparatus comprises an identifying unit to obtain identity information of the connecting lines by the measuring apparatus.

17. The automatic measuring apparatus as claimed in claim 16, wherein the identifying unit is adapted for searching in data centers regarding the identity information and affirming types of the connecting lines according to searching results, for loading the setting parameters and the measuring regulations into the automatic measuring apparatus.

18. The automatic measuring apparatus as claimed in claim 17, wherein indexes adapted for searching the types of the connecting lines through the identity information are stored in the data centers.

19. The automatic measuring apparatus as claimed in claim 16, wherein the connecting lines each have a unique mark for representing their corresponding identity, the automatic measuring apparatus being capable of automatically scanning the unique marks of the connecting lines to automatically collect the identity information of the connecting lines.

20. The automatic measuring apparatus as claimed in claim 19, wherein the unique mark is barcode or Radio Frequency Identification (RFID).
